(19) United States
(12) Patent Application Publication
(10) Pub. No.: US 2003/0235973 A1
(43) Pub. Date: Dec. 25, 2003

(54) Nickel SALICIDE process technology for CMOS devices

(76) Inventors: Jiong-Ping Lu, Richardson, TX (US); Donald S. Miles, Plano, TX (US); Ching-Te Lin, Plano, TX (US); Jin Zhao, Plano, TX (US); April Gurba, Plano, TX (US); Yuqing Xu, Plano, TX (US)

Correspondence Address: Jackie Garner, Texas Instruments Incorporated, P.O. Box 655474, M/S 3999, Dallas, TX, 75265, US

(21) Appl. No.: 10/177,269

(22) Filed: Jun. 21, 2002

(51) Int. Cl. H01L 21/22

(52) U.S. Cl. 438/555

(57) ABSTRACT

A novel nickel self-aligned silicide (SALICIDE) process technology (80) adapted for CMOS devices (54) with physical gate lengths of sub-40 nm. The excess silicidation problem (52) due to edge effect is effectively solved by using a low-temperature, in-situ formed Ni-rich silicide, preferably formed in a temperature range of 260-310° C. With this new process, excess poly gate silicidation is prevented. Island diode leakage current and breakdown voltage are also improved.

### FIELD OF THE INVENTION

The present invention is related to semiconductor processing techniques, and more specifically to processes for forming SALICIDES as contacts on a wafer substrate.

### BACKGROUND OF THE INVENTION

Self-aligned suicides (SALICIDEs) are widely used in CMOS fabrication for contacts to a gate, source and drain. In a SALICIDE process, a metal (Ti, Co or Ni) is deposited on a wafer substrate with gate stack and source/drain openings. An optional capping layer (Ti or TiN) can also be deposited in the same cluster tool where the metal film is deposited. The wafers with deposited films are conventionally moved to a different tool for rapid thermal anneal to form initial phase of silicides. Four initial phases of suicides are C-49 TiSi2, CoSi and NiSi, for Ti, Co and NiSi respectively. The un-reacted portion of metal layer is then selectively etched (stripped) to leave only silicide on top of the gate, source and drain.

As physical dimensions of CMOS devices, including gate length and junction depth, continue to shrink, nickel (Ni) SALICIDE is becoming an attractive candidate to replace cobalt (Co) SALICIDE for aggressively scaled structures. Among the major advantages of NiSi are: low sheet resistance for small gate length, low Si consumption, low stress and low process temperature (beneficial for reducing dopant loss). However, there is a significant problem in using NiSi for small poly lines and island diodes, where excess silicidation occurs due to edge effect.

A novel process is needed to effectively solve the problem of excess silicidation due to edge effect.

### SUMMARY OF THE INVENTION

The present invention achieves technical advantages as a novel process technology for fabricating NiSi through in-situ formed Ni-rich silicide intermediate. Using the new process of the present invention, gate silicidation is controlled, and island diode breakdown voltage as well as leakage current is improved. NiSi is a promising material for sub-40 nm CMOS devices, where CoSi2 suffers from narrow line effect. The excess silicidation observed for NiSi prepared using a conventional process is advantageously overcome using the present invention.

The present invention is a process of fabricating NiSi through the use of an Ni-rich intermediate. The steps include depositing an Ni film with or without an optional cap on a semiconductor portion, such as a gate, source and drain, and in-situ annealing the Ni film in the same cluster tool to form Ni-rich silicide. Thereafter, the un-reacted metal is selectively removed. Lastly, the Ni-rich silicide is annealed to form NiSi. Advantageously, the in-situ annealing is performed at a low temperature, preferably in the range of 260-310 C. to significantly reduce excess silicide formation on the device.

According to an alternative embodiment, the present invention comprises the steps of depositing an Ni film in the temperature range of 250-310 C. to form an Ni rich silicide upon the selected region of the semiconductor substrate. Thereafter, the un-reacted metal is selectively removed. Finally, the Ni-rich silicide is annealed to form NiSi.

The advantages of the present invention include that the Ni-rich silicide is formed at a low temperature, avoiding the excess silicide formation using conventional methods. In addition, both the Ni deposition and silicidation can be performed in the same cluster tool, using a single process sequence. No extra log point is needed as compared with current designs. The method is a lower cost and simplified device flow as compared to conventional two-RTA processes. Moreover, in-situ formation of silicide is achieved without breaking vacuum, eliminating the ambient effect and the need of a capping layer. This helps improve film quality and further reduces cost-of-ownership. The temperature control is also more reproducible than conventional RTA in the temperature range needed for the Ni-rich silicide formation.

### BRIEF DESCRIPTION OF THE DRAWINGS

FIG. 1 is a graph of the sheet resistance for n-Poly as a function of physical gate length;

FIG. 2 is a graph of the sheet resistance for p-Poly as a function of physical gate length;

FIG. 3A is a conventional flow process for Ni silicide, and FIG. 3B depicts this process;

FIG. 4 is a TEM cross-section image of an n-gate with excess silicidation;

FIG. 5 is a graph depicting the sheet resistance and non-uniformity as a function of form temperature for a Ni film on Si;

FIG. 6 is a graph depicting the XPS depth profile for Ni on Si annealed at 360° C.;

FIG. 7 is a graph depicting the XPS depth profile for Ni on Si annealed at 290° C.;

FIG. 8A is a flow diagram of the process of the present invention for fabricating NiSi through in-situ formed NixSi (x>1) intermediate, according to the present invention; and FIG. 8B depicts this process;

FIG. 9 is a TEM cross-section image of an n-gate using NiSi formed through in-situ NixSi, according to the present invention;

FIG. 10 is a chart depicting the breakdown voltage for n-island diodes, showing NiSi using a conventional process, and using the process of the present invention; and

FIG. 11 depicts a graph of the leakage current for an n-island diode, showing NiSi according to a conventional process, and showing NiSi according to the present invention.

### DETAILED DESCRIPTION OF THE PREFERRED EMBODIMENT

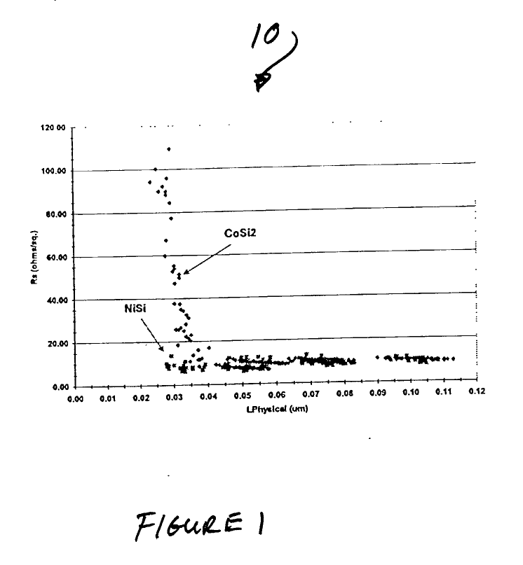

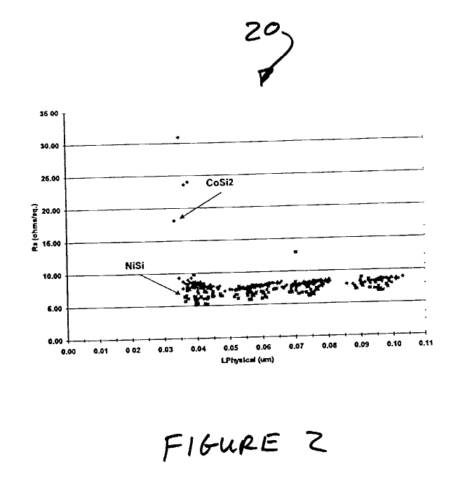

Sheet resistance for n-Poly and p-Poly as a function of physical gate length is shown at 10 and 20 in FIGS. 1 and 2, respectively. As observed from the data, the CoSi2 sheet resistance becomes un-acceptably high and widely distributed for poly lines below 40 nm. On the other hand for NiSi, tight distribution with low sheet resistance can be achieved for poly lines down to below 30 nm.

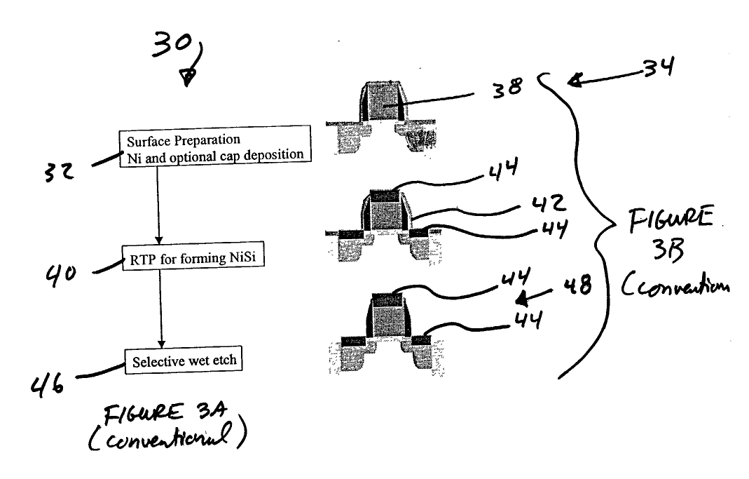

A conventional process for fabricating Ni SALICIDE is shown at 30 in FIG. 3A, with the fabrication of the Ni SALICIDE for each step being illustrated in corresponding FIG. 3B. At step 32, a surface of the wafer, such as a gate, source and drain, is prepared and an Ni film followed by an optional TiN or Ti cap is deposited, as shown at 34, whereby the gate, source and drain with the Ni film being shown at 38. Next, at step 40, the wafer is then subjected to RTP at a high temperature, usually being in the range of 400-550° C. As depicted at 42, excess silicidation is disadvantageously formed with the formed NiSi SALICIDE being shown at 44. Finally, at step 46, a selective wet etch is preformed to remove unreacted metal and optional cap, as shown at 48.

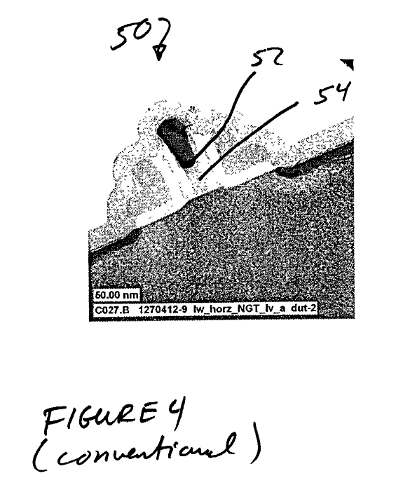

A TEM cross-section image for self-aligned contacts prepared using the above conventional procedure is shown in FIG. 4 at 50. As seen clearly in FIG. 4, excess silicidation is observed at 52 for the narrow poly line 54. This excess silicidation 52 can cause poly depletion and affect transistor performance. The excess silicidation 52 also occurs on small diodes structures such as island diode, which results in excess leakage current (to be discussed in more detail shortly). One possible mechanism for the excess silicidation 52 is the diffusion of Ni atoms from regions surrounding the small Si feature structures during the RTP silicidation step.

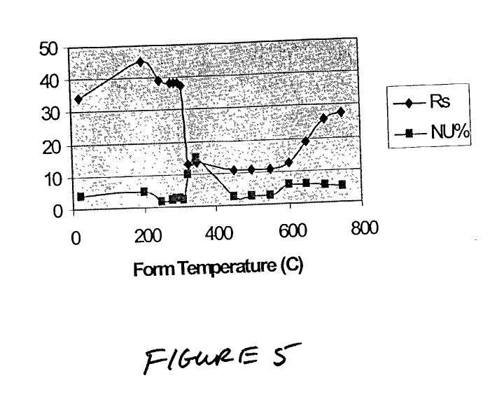

FIG. 5 shows sheet resistance Rs and non-uniformity (NU %) responses as a function of form temperature for a Ni film on Si. As observed from FIG. 5, there are two temperature windows where Rs are stable and non-uniformity is good: one in the range of 260-310° C. and the other in the range of 400-550° C. The later range is conventionally used for forming NiSi. Due to its high temperature, excess silicidation is a problem in this temperature range as previously discussed and illustrated in FIG. 4.

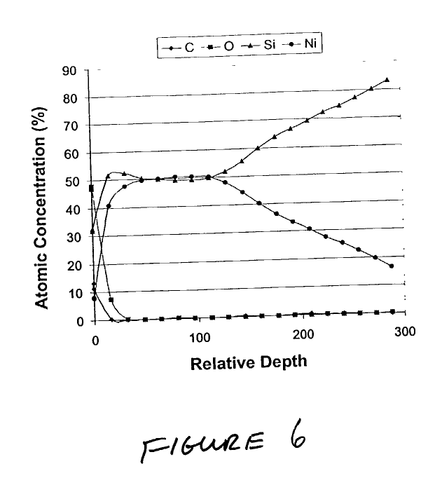

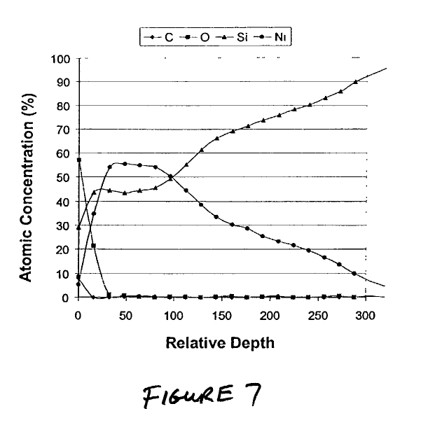

According to the present invention, the low temperature window is used in order to minimize excess silicidation problem. XPS results shown in FIGS. 6 and 7 indicate that the silicide formed in the low temperature 260-310° C. window is Ni-rich. FIG. 6 illustrates XPS depth profile for Ni on Si annealed at 360° C., while FIG. 7 illustrates XPS depth profile for Ni on Si annealed at 290° C. Wet-etch test results show that excellent selectivity can be achieved by using H2SO4/H2O2/H2O solution (sulfuric-hydrogen peroxide mixture, SPM) for the Ni-rich silicide. Table I summarizes opti-probe results for a Ni film on SiO2 annealed at 300° C. before and after wet etch.

TABLE I

| Sample # | 4 | 5 | 6 |
|---|---|---|---|
| SPM Time | 0 | 0 | 0 |
| Layer 1 THK | 459.93 | 462.53 | 456.52 |
| GOF | 0.83 | 0.83 | 0.82 |
| SPM Time | 200 | 400 | 800 |
| Layer 1 THK | 1002.8 | 1000.83 | 997.95 |
| GOF | 0.99 | 1.00 | 1.00 |

As observed, the metal film on non-reactive SiO2 surface can be cleanly removed after just 200 sec of wet etch. On the other hand, no significant loss of formed silicide was observed after even 800 sec of wet etch, as shown in four-point probe results of Ni/Si annealed at 300° C. before and after wet etch(see Table II).

TABLE II

| Sample # | 1 | 2 | 3 |
|---|---|---|---|
| SPM Time | 0 | 0 | 0 |
| Mean (Ohm/sq) | 38.93 | 39.13 | 39.07 |
| SPM Time | 200 | 400 | 800 |
| Mean (Ohm/sq) | 39.07 | 39.34 | 39.23 |

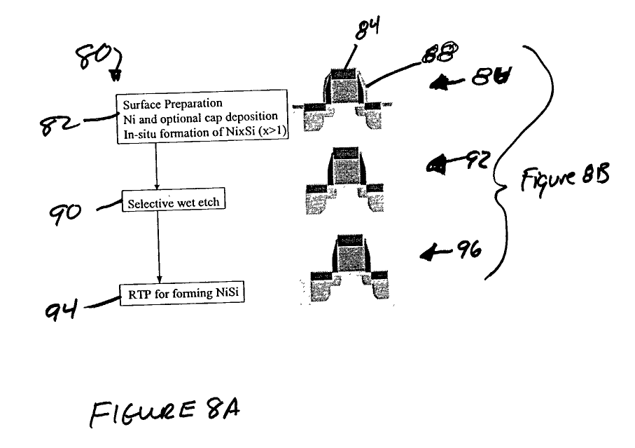

With the low temperature process window identified and selectivity established, the present invention advantageously is a new process technology for NiSi fabrication. FIGS. 8A and 8B are a flow diagram 80 and pictorial illustration of the process flow to fabricate NiSi through an in-situ formed Ni-rich silicide, respectively. At step 82, after the deposition of a Ni film 84 followed by an optional TiN or Ti cap, the wafer is then annealed in-situ at a temperature within the low temperature window 260-310° C. for silicidation, in the same deposition cluster tool, as shown at 86. At this low temperature, Ni diffusion from surrounding region is negligible in causing excess silicidation problem 88. The un-reacted Ni and TiN or Ti cap is then removed by selective wet etch at step 90, as shown at 92. The wafer is then subjected to a single RTP at step 94 at a temperature within the high temperature window 400-550° C., which converts silicide into low resistivity phase NiSi. During this RTP step, there is no excess Ni surrounding the small active features (such as gates and island diodes) as shown at 96, therefore, the excess silicidation problem is minimized. Although there is two thermal steps involved in this new flow, there is no extra logpoint needed due to the use of in-situ form step in the same cluster tool as Ni deposition.

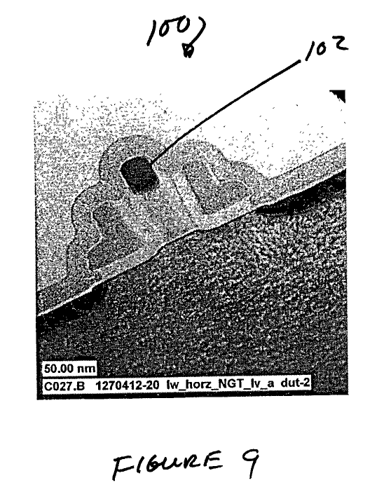

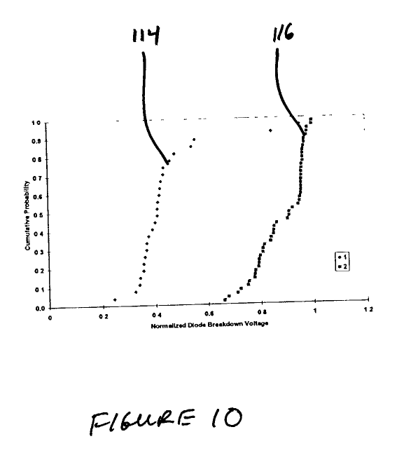

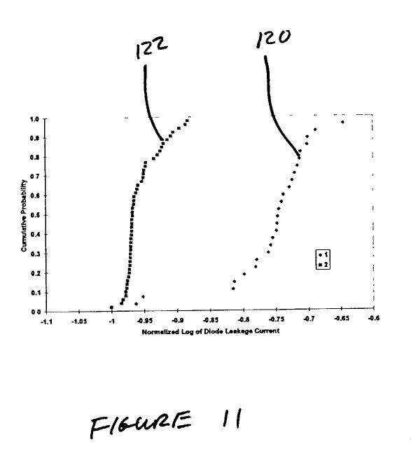

The success of the new process has been confirmed by TEM cross-section image as shown at 100 in FIG. 9 depicting the NiSi SALICIDE contact at 102. As observed from the picture, the excess gate silicidation 52 observed in FIG. 4 is greatly reduced. The improvement in reducing excess silicidation is also shown in parametric probe data in FIGS. 10 and 11. The island diode breakdown voltage is significantly increased for the diodes with new process shown at 116 than those with a conventional process, shown at 114. Consistent with this observation, the island diode leakage current is greatly reduced for the diodes fabricated with the new process as shown in FIG. 11, where the conventional process is shown at 120, and according to the new process at 122.

The advantages of the present invention include that the Ni-rich silicide is formed at low temperature, avoiding excess silicide formation formed during conventional methods. In addition, both the Ni deposition and silicidation can be performed in the same cluster tool, using a single process sequence. No extra log point is needed as compared with current designs. The method is a lower cost and simplified device flow as compared to conventional two-RTA processes. Moreover, in-situ formation of silicide is achieved without breaking vacuum, eliminating the ambient effect and potentially the need of a capping layer. This helps improve film quality and further reduces cost-of-ownership. The temperature control is also more reproducible than conventional RTA in the temperature range needed for the Ni-rich silicide formation.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

We claim:

1. A method of fabricating a self-aligned silicide upon a semiconductor wafer, comprising the steps of:
depositing a Ni film upon the semiconductor wafer;
annealing the Ni film in-situ to form Ni-rich silicide;
selectively removing the un-reacted Ni film; and
annealing the Ni-rich suicide to form NiSi.

2. The method as specified in claim 1 wherein the Ni film is deposited and annealed using a common cluster tool.

3. The method as specified in claim 1 wherein the Ni film is annealed at a temperature range of 250 to 310° C. to form the Ni-rich silicide.

4. The method as specified in claim 1 wherein the Ni film is deposited with a cap layer selected from the group consisting of TiN and Ti.

5. The method as specified in claim 1 wherein the semiconductor device comprises a gate, drain and source.

6. The method as specified in claim 1 wherein the semiconductor device comprises an island diode.

7. The method as specified in claim 1 wherein the annealing of the Ni-rich silicide is performed in a single step.

8. A method of fabricating a self-aligned silicide upon a semiconductor wafer, comprising the steps of:
depositing a Ni-film upon the semiconductor wafer at a temperature between 250 to 310° C. to form Ni-rich silicide;
selectively removing the un-reacted Ni-film; and
annealing the Ni-rich silicide to form NiSi.

9. The method as specified in claim 8 wherein the Ni film is deposited and annealed using a common cluster tool.

10. The method as specified in claim 8 wherein the Ni film is deposited with a cap layer selected from the group consisting of TiN and Ti.

11. The method as specified in claim 10 wherein the semiconductor device comprises a gate, drain and source.

12. The method as specified in claim 10 wherein the semiconductor device comprises an island diode.

13. The method as specified in claim 8 wherein the annealing of the Ni-rich silicide is performed in a single step.

14. A semiconductor having an Ni-Si silicide formed using the steps of:
depositing a Ni film upon the semiconductor wafer;
annealing the Ni film in-situ to form Ni-rich silicide;
selectively removing the un-reacted Ni film; and
annealing the Ni-rich silicide to form NiSi.

15. The method as specified in claim 14 wherein the Ni film is deposited and annealed using a common cluster tool.

16. The method as specified in claim 14 wherein the Ni film is annealed at a temperature range of 250 to 310° C. to form the Ni-rich silicide.

17. A semiconductor having an Ni-Si silicide formed using the steps of:
depositing a Ni-film upon the semiconductor wafer at a temperature between 250 to 310° C. to form Ni-rich silicide;
selectively removing the un-reacted Ni-film; and
annealing the Ni-rich silicide to form NiSi.

18. The method as specified in claim 17 wherein the Ni film is deposited and annealed using a common cluster tool.

19. The method as specified in claim 17 wherein the annealing of the Ni-rich silicide is performed in a single step.

20. The method as specified in claim 17 wherein the semiconductor comprises an island diode.
